(19) United States
(12) Patent Application Publication
(10) Pub. No.: US 2002/0159607 A1
(43) Pub. Date: Oct. 31, 2002

(54) Method for using source content information to automatically optimize audio signal

(76) Inventors: Jeremy M. Ford, Austin, TX (US); Mitchell A. Markow, Austin, TX (US)

Correspondence Address: CONLEY ROSE & TAYON, P.C., P. O. BOX 3267, HOUSTON, TX, 77253-3267, US

(21) Appl. No.: 09/844,355

(22) Filed: Apr. 26, 2001

(51) Int. Cl. H03G 5/00

(52) U.S. Cl. 381/103; 381/98

(57) ABSTRACT

An audio system that automatically customizes equalization and gain of sound based on sound type includes a controller coupling together a digital audio source, a digital equalizer, equalization coefficient database, and source information database. The digital equalizer receives a digital audio signal from the digital audio source. The digital audio source contains digital audio media containing a number of sound selections and transmits a sound selection header to the controller. The controller transmits the sound selection header to the source information database. The source information database provides a sound type corresponding to the sound selection header to the controller. After receiving the sound type from the source information database, the controller transmits the sound type to the equalization coefficient database. The equalization coefficient database then provides the audio signal processing coefficients corresponding to the sound type to the controller and the controller automatically updates digital equalizer parameters.

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND OF THE INVENTION

1. Field of the Invention

The present invention relates generally to systems that perform signal processing on audio from a digital media source. More particularly, the invention relates to an apparatus and method for using audio source content information to automatically optimize audio output based on the sound type (e.g., jazz music, country music or motion picture conversation). Still more particularly, the present invention relates to systems that use header information stored in audio selections from a digital media source to determine the type of sound and digital equalization coefficients using database lookups.

2. Background of the Invention

Audio systems are designed to faithfully reproduce audio source material for a given user specified environment as intended by the creator of the source material. Audio source material may come from a large number of different kinds of sound types such as music or movie soundtracks. Different types of music that may have to be reproduced by the audio system include Jazz, Rock, Classical, Country, Pop, etc. The audio system user may use the audio system to play music or movie soundtracks stored on an audio source such as a Compact Disc (“CD”), or Digital Video Disc (“DVD”).

Audio recordings comprise a group of frequencies of varying amplitude. Modern audio systems can take an audio recording and split the recording into component frequencies that can then be independently amplified or enhanced. Equalization of the recorded audio signal, in which some frequency components are amplified in amplitude while other frequency components are reduced in amplitude, results in a more life-like reproduction of the stored audio signal. For different types of music and other sound recordings, high quality reproduction requires that different groups of frequency components be amplified and reduced. Prior designs for audio systems have incorporated amplification/reduction of the same group of frequency components regardless of the type of sound. Such fixed frequency response audio systems compromised the life-like quality of the reproduced sound to reduce design cost and system complexity. Other prior audio system designs have incorporated user adjustable equalization settings. Such systems allow users to manually adjust equalization settings for different types of sound; however, these audio systems are very user intensive and difficult to use since obtaining optimal performance requires constant user interaction.

With the advent of digital audio media (e.g., CD, digital audio tape (“DAT”), DVD), hard disk drives and floppy diskettes containing compressed digital audio files such as MPEG Audio Layer 3 (“MP3”) information may be encoded into the header of each selection stored on the digital audio media. This information may include a code that is unique to the selection stored on the digital media. The code identifies the artist, title, sound type, etc. of the selection.

It would be advantageous if an apparatus and method for adjusting the equalization settings in an audio system based on the type of sound for a selection could be devised that requires no user input. It would also be advantageous if the audio system could automatically determine the sound type from the header code encoded into the music and determine the equalization parameters by performing a database lookup. Such a system would be able to perform automated real-time optimization for the type of sound being played. Despite the apparent advantages of such a system, to date no such system has been implemented.

### BRIEF SUMMARY OF THE INVENTION

The problems noted above are solved in large part by an audio system that automatically customizes equalization and gain of sound based on sound type. The audio system preferably includes a controller that couples a digital audio source, a digital equalizer, equalization coefficient database, a source information database, power amplifier, and a speaker. The digital equalizer receives a digital audio signal from the digital audio source. The digital audio source contains digital audio media containing a number of sound selections and transmits a sound selection header to the controller. The controller transmits the sound selection header to the source information database. The source information database provides a sound type corresponding to the sound selection header to the controller. After receiving the sound type from the source information database, the controller transmits the sound type to the equalization coefficient database. The equalization coefficient database after receiving the sound type from the controller, provides the audio signal processing coefficients corresponding to the sound type to the controller. The controller then automatically updates digital equalizer parameters by applying the audio signal processing coefficients to the digital equalizer.

The controller can be implemented as a digital signal processor or a software application executing on a microprocessor in a computer system. Both the source information database and the equalization coefficient database can each be online databases remotely accessed by the controller or, if the controller is implemented on a microprocessor in a computer system, can be stored on storage media of the computer system.

### BRIEF DESCRIPTION OF THE DRAWINGS

For a detailed description of the preferred embodiments of the invention, reference will now be made to the accompanying drawings in which:

FIG. 1 shows the apparatus that uses source content information to automatically optimize audio signal processing in accordance with the preferred embodiment of the invention;

FIG. 2 shows the organization of a sound selection stored on digital audio media in accordance with the preferred embodiment of the invention;

FIG. 3 shows the source information database table including a header code that indexes the sound type;

FIG. 4 shows the equalization coefficient database table that contains the audio signal processing coefficients indexed by each sound type; and

FIG. 5 shows the digital equalization hardware of the preferred embodiment that performs equalization and gain control of the input signal and real time update of the signal processing equalization coefficients.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . .”. Also, the term “couple” or “couples” is intended to mean either an indirect or direct electrical connection. Thus, if a first device couples to a second device, that connection may be through a direct electrical connection, or through an indirect electrical connection via other devices and connections.

### DETAILED DESCRIPTION OF THE PREFERRED EMBODIMENTS

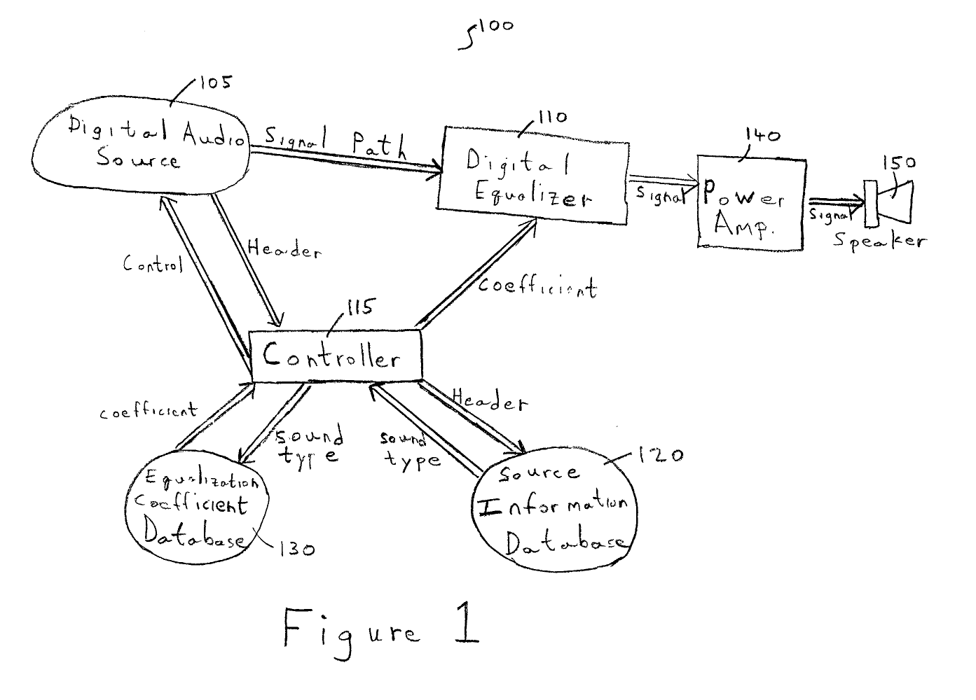

Referring now to FIG. 1, in accordance with the preferred embodiment of the invention, audio system 100 comprises a digital audio source 105 that may preferably be a compact disc player or digital video disc player. The digital audio source 105 has the capability to play back digital audio media (e.g., CDs or DVDs) to generate an audio signal to a digital equalizer 110. The digital audio media preferably contains a number of audio selections with each audio selection containing a starting header uniquely identifying the audio selection. An audio selection may preferably be a song, a conversation, or a portion of a motion picture soundtrack and is preferably organized to include a starting header, followed by the audio selection content. The digital audio source sends the starting header to controller 1 15 and the digital audio selection content to the digital equalizer 110. Digital audio source 105 receives control information from controller 115. Preferably, the controller 115, responding to system or user instructions, may instruct the digital audio source to reproduce a particular audio selection or perform any number of other functions on the audio selection (e.g., fast forward, rewind, pause etc.).

Digital audio source 105 is controlled by controller 115. Controller 115 preferably receives header information from the digital audio source 105 identifying audio selections stored on the digital audio media. The controller 115 sends the header information for an audio selection to a source information database 120 and receives the sound type from the source information database 120. Controller 115 then sends the sound type to an equalization coefficient database 130 and receives equalization coefficients from the equalization coefficient database 130. Controller 115 outputs equalization coefficients to the digital equalizer 110. After the digital equalizer 110 performs equalization of the signal from the digital audio source 105 using the coefficients supplied by controller 115, the signal is sent to power amplifier 140 which is then sent to speaker 150. Audio system 100 is described in more detail below.

Digital equalizer 110 preferably performs digital equalization, dynamic range compression and gain control. As explained above, digital equalization is the process by which some frequency components of the audio signal are amplified while other frequency components are reduced. Dynamic range compression is used in stereophonic audio systems to scale audio signal amplitudes within a certain range of values that satisfy a user specified amplification volume request. Gain control is the amplification or reduction of the output signal from the digital equalizer based on the amplitude of the input signal. The gain of the audio system is user specified by setting the amplification volume request and is the ratio between the input and output signals. The digital equalizer 110 receives audio equalization coefficients that update parameters of the digital equalizer based on the type of sound currently selected. The digital equalizer 110 also performs digital-to-analog conversion of the audio signal after the signal has been equalized, range compressed and gain controlled and sends the analog audio signal to power amplifier 140.

In accordance with the preferred embodiment of the invention, power amplifier 140 receives an analog audio signal from digital equalizer 110 and amplifies the signal. The power amplifier 140 preferably comprises a standalone unit or may be incorporated with the speaker 150. Power amplifier 140 sends the amplified, analog audio signal to audio speaker 150, which then converts the audio signal to sound waves.

Controller 115 may be a computer system that includes an Application Specific Integrated Circuit (“ASIC”), a microcontroller or a microprocessor that can control real time acquisition and updating of the signal processing coefficients needed to implement the preferred embodiment of the invention in accordance with FIG. 1. Preferably, controller 115 receives start header information from the digital audio source 105 for a particular audio selection. The controller 115 identifies the audio selection content type using the start header by transmitting the start header to a source information database that returns the type of sound and other information about the sound. The controller 115 correlates the sound type with specified audio signal processing coefficients by performing an equalization coefficient database 130 lookup. The coefficients determined from the equalization coefficient database 130 lookup are used by the digital equalizer 110 to perform digital parametric equalization as described above.

In accordance with the preferred embodiment of the invention, the source information database 120 may be a World Wide Web online database external to audio system 100 or may be a local database stored in storage media of the computer system controller 115. Source information database 120 allows the correlation of start header information with the type of sound and other identifying information for the audio selection as described in more detail below. In one preferred embodiment, a World Wide Web online database such as cddb.com (Compact Disc DataBase) including a Disc Recognition Service (“DRSTM”) can be used to perform the start header lookup to determine the sound type.

Equalization coefficient database 130 in the preferred embodiment of the invention may be stored on storage media in audio system 100. The equalization coefficient database 100 includes audio signal processing coefficients for each type of sound. Preferably, the audio signal processing coefficients may be digital filter coefficients for any number of different digital filters such as Butterworth digital filters or Chebyshev digital filters. Equalization coefficient database 130 receives the sound type from controller 115 and returns the signal processing coefficients corresponding to the sound type to controller 115.

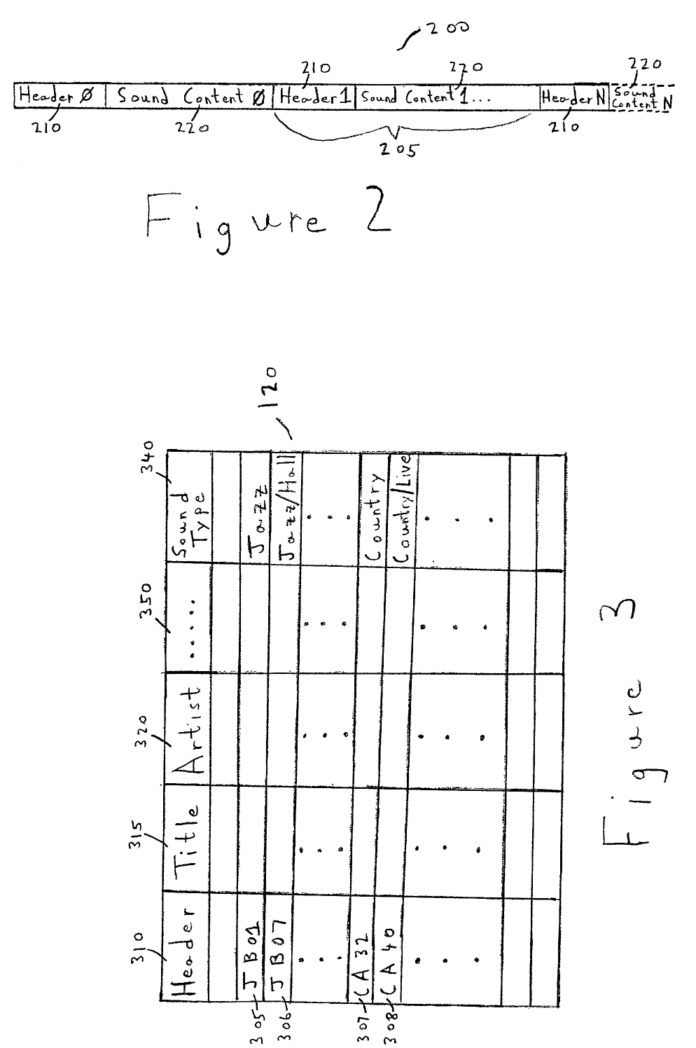

Turning now to FIG. 2, in one exemplary embodiment each music or movie soundtrack selection 205 stored on the digital audio media 200 is organized to begin with start header information 210 and follow with the sound content 220 of the selection 205. The header 210 and sound content 220 are stored in a digital binary format (i.e., ones and zeros) on the digital audio media 200. In another exemplary embodiment, start header 210 may be placed after sound content 220 for each music or movie soundtrack selection 205. Alternatively, in a third exemplary embodiment, all start header fields 210 may be grouped together in one portion of the digital audio media 200 in a predetermined order followed by all of the music or movie soundtrack selections 205 in the same predetermined order. Digital audio source 105 includes hardware that for each selection 205 reads the start header 210 prior to reading the corresponding sound content 220 regardless of the location of the start header 210 relative to the sound content 220 as described above.

Turning now to FIG. 3, in accordance with the preferred embodiment of the invention, source information database 120 includes entries 305-308 for start header types. Each start header type 310 identifies a title 315, artist 320, sound type 340 and other information 350 helpful for playback and source identification. Sound type 340 corresponds to one type of music reproduced for optimal sound in a particular surrounding. In one example, a music selection with start header type “JB01” corresponds to a sound type “Jazz” played in no particular setting and in another example a start header “JB07” corresponds to a sound type “Jazz/Hall” played in a music hall setting. As described above, source information database 120 may be a World Wide Web online database external to audio system 100 or may be a local database stored in storage media of the computer system controller 115. New entries in the source information database 120 can be added as new sound types are created.

Preferably, source information database 120 may be implemented as a lookup table array structure, linked list or another class of data structure allowing fast retrieval of information based on a start header type 310 lookup key. For high-speed retrieval, commercial databases can store the data contained in source information database 120.

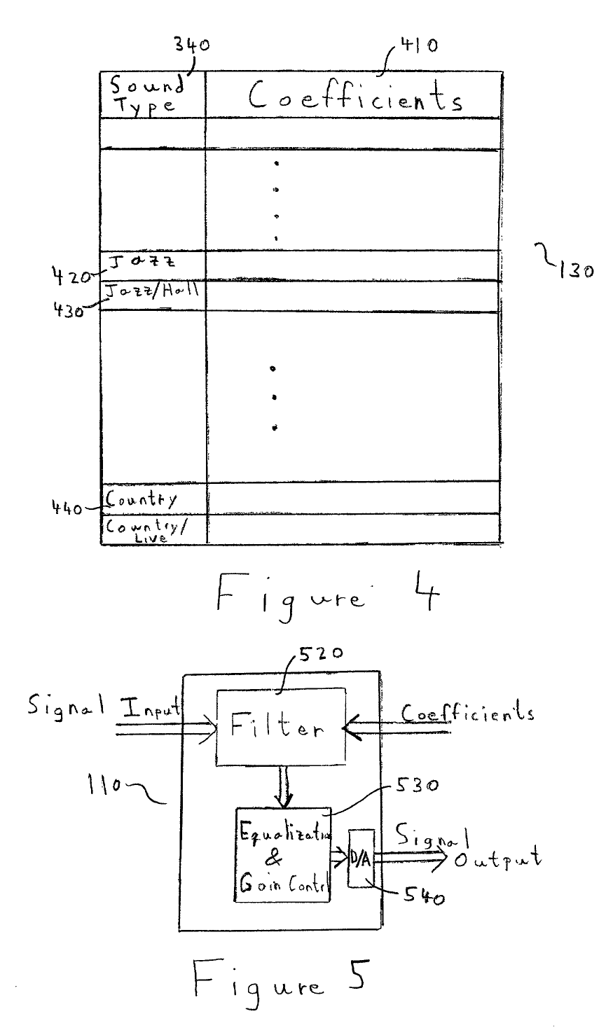

FIG. 4, in accordance with the preferred embodiment of the invention, shows equalization coefficient database 130 including entries for different categories 420-440 of sound types 340. Each category 420-440 of sound type 340 in the equalization coefficient database corresponds to a start header type 310 of the source information database 120. A sound type 310 in the equalization coefficient database 130 determines the audio signal processing coefficients 410 needed by the digital equalizer for optimal reproduction of each type of sound. Preferably, the audio signal processing coefficients 410 are digital filter coefficients for any number of different digital filters such as Butterworth digital filters or Chebyshev digital filters. Equalization coefficient database 130 may be a World Wide Web online database external to audio system 100 or may be a local database stored in storage media of the computer system controller 115. As new sound types 340 are created, the equalization coefficient database 130 is updated with the new sound type and coefficients.

Referring now to FIG. 5, the digital equalizer 110 of the preferred embodiment performs equalization and gain control of the input signal as well as real time update of the signal processing equalization coefficients. Filter 520 that is preferably a digital filter receives the digital input signal from digital audio source 405 and audio signal processing coefficients from controller 115. The digital filter 520 performs digital filtering of the input signal and outputs the filtered signal to equalization and gain control 530. The equalized and gain adjusted digital signal is then sent to digital-to-analog converter 540 that converts the digital signal to an analog signal and outputs the signal to power amplifier 140.

Digital equalizer 110 of the preferred embodiment can be implemented as application specific hardware for filtering, equalization, and gain control. Alternatively, digital equalizer 110 may be implemented as a software application executing on a host microcontroller, microprocessor, or Digital Signal Processor (“DSP”) to perform the functions of digital filtering, equalization and gain control.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. An audio system that automatically generates optimal sound based on sound type, comprising:
a controller;
a digital audio source coupled to said controller, wherein said digital audio source is capable of receiving digital audio media, said digital audio source reading a sound selection header from the digital audio media and transmitting said header to the controller;
a digital equalizer coupled to said controller, said digital equalizer receiving a digital audio signal from the digital audio source; and
wherein said controller based on the header automatically updates digital equalizer parameters by applying audio signal processing coefficients to the digital equalizer.

2. The audio system of claim 1 further comprising a source information database coupled to said controller, said source information database receiving the sound selection header from the controller and providing a sound type corresponding to the sound selection header to the controller.

3. The audio system of claim 2 wherein the source information database is an online database.

4. The audio system of claim 1 wherein the sound selection header identifies a type of sound stored in the digital audio source.

5. The audio system of claim 1 further comprising an equalization coefficient database coupled to said controller, said equalization coefficient database receiving the type of sound from the controller and providing the audio signal processing coefficients corresponding to the type of sound to the controller.

6. The audio system of claim 5 wherein the equalization coefficient database is an online database.

7. The audio system of claim 1 wherein the controller is a digital signal processor (“DSP”).

8. The audio system of claim 1 wherein the controller is a software application executing on a microprocessor in a computer system.

9. The audio system of claim 8 wherein the source information database is stored on storage media of the computer system.

10. The audio system of claim 8 wherein the equalization coefficient database is stored on storage media of the computer system.

11. The audio system of claim 1 wherein the digital audio media is a compact disc formatted to include a plurality of said sound selections, each sound selection containing said sound selection header and sound content.

12. A method of automatically generating optimal sound from a digital audio media based on the type of sound stored on the digital audio media, comprising:
reading a sound selection header from the digital audio media;
determining audio signal processing coefficients using the sound selection header; and
updating digital equalizer parameters by applying the audio signal processing coefficients to the digital equalizer.

13. A method as in claim 12 wherein determining audio signal processing coefficients comprises performing a lookup of sound type corresponding to the sound selection header in a source information database.

14. A method as in claim 13 wherein determining audio signal processing coefficients further comprises performing a lookup of the audio signal processing coefficients corresponding to the sound type in an equalization coefficient database.

15. A method as in claim 14 wherein the equalization coefficient database is an online database.

16. A method as in claim 12 wherein the digital audio media is a compact disc formatted to include a plurality of sound selections, each sound selection containing said sound selection header and sound content.

17. An audio system that automatically generates optimal sound based on sound type, comprising:
a controller;
a digital audio source coupled to said controller, wherein said digital audio source is capable of receiving at least one digital audio media containing sound recordings, said digital audio source identifying a sound selection header and transmitting said sound selection header to said controller;
a digital equalizer coupled to said controller, said digital equalizer receiving a digital audio signal from the digital audio source;
a first database coupled to said controller, said first database receiving the sound selection header from the controller, determining a sound type corresponding to the sound selection header, and providing a signal identifying the sound type;
a second database coupled to said controller, said second database receiving the sound type from the controller and providing audio signal processing coefficients corresponding to the sound type to the controller; and
wherein said controller based on the sound type automatically updates digital equalizer parameters by applying the audio signal processing coefficients to the digital equalizer.

18. An audio system that automatically generates optimal sound based on sound type, comprising:
a digital audio source, wherein said digital audio source is capable of receiving digital audio media, said digital audio source reading a sound selection header from the digital audio media; and
a digital equalizer coupled to said digital audio source, said digital equalizer receiving a digital audio signal from the digital audio source, wherein said digital equalizer based on the sound selection header automatically updates digital equalizer parameters by applying audio signal processing coefficients.

19. The audio system of claim 18 further comprising a source information database coupled to said digital audio source, said source information database receiving the sound selection header from the digital audio source and providing a sound type corresponding to the sound selection header to an equalization coefficient database.

20. The audio system of claim 19 wherein said equalization coefficient database providing the audio signal processing coefficients corresponding to the type of sound to the digital equalizer.
